(19) United States
(12) Patent Application Publication
(10) Pub. No.: US 2024/0183029 A1
(43) Pub. Date: Jun. 6, 2024

(54) DEPOSITION APPARATUS AND DEPOSITION METHOD USING THE SAME

(71) Applicant: Samsung Display Co., LTD., Yongin-si (KR)

(72) Inventors: HYUNEOK SHIN, Yongin-si (KR); JOONYONG PARK, Yongin-si (KR)

(21) Appl. No.: 18/376,202

(22) Filed: Oct. 3, 2023

(30) Foreign Application Priority Data
Dec. 6, 2022 (KR) 10-2022-0168314

(51) Int. Cl. C23C 14/56; C23C 14/35; C23C 14/50; H01J 37/32; H01J 37/34

(52) U.S. Cl. CPC C23C 14/568; C23C 14/35; C23C 14/50; H01J 37/32715; H01J 37/3429; H01J 37/3435; H01J 2237/2007; H01J 2237/202; H01J 2237/332; H01L 27/1259

(57) ABSTRACT

A deposition apparatus includes a chamber in which an inner space is defined, a movement device which moves a substrate to which a deposition material is provided, and a deposition source which is accommodated in the inner space and provides the deposition material. The deposition source includes a first deposition source which performs a first deposition process while the substrate is moved in a first direction by the movement device and a second deposition source which performs a second deposition process on the substrate after the first deposition process.

This application claims priority to Korean Patent Application No. 10-2022-0168314, filed on Dec. 6, 2022, and all the benefits accruing therefrom under 35 U.S.C. § 119, the content of which in its entirety is herein incorporated by reference.

### BACKGROUND

### 1. Field

Embodiments of the present disclosure described herein relate to a deposition apparatus and a deposition method using the deposition apparatus.

### 2. Description of the Related Art

Electronic devices, such as a smart phone, a digital camera, a notebook computer, a car navigation unit, a smart television, and the like, which provide an image to a user include a display device for displaying an image. The display device generates an image and provides the generated image to the user through a display screen. During manufacture of the display device, a sputtering process may be used.

A sputtering technology is a film formation technology in which plasma is used to generate ions that strike a sputtering target such that atoms of the sputtering target are deposited as a film on a substrate. The sputtering technology may be used to create metal, oxide, nitride, and a semiconductor thin film in various manufacturing processes used especially in the semiconductor and photoelectric industries.

### SUMMARY

Embodiments of the present disclosure provide a deposition apparatus for depositing a thin deposition layer having a uniform thickness on a substrate and a deposition method using the deposition apparatus.

According to an embodiment, a deposition apparatus includes a chamber that provides an inner space, a movement device which moves a substrate to which a deposition material is provided, and a deposition source accommodated in the inner space, where the deposition source provides the deposition material. In such an embodiment, the deposition source includes a first deposition source which performs a first deposition process while the substrate is moved in a first direction by the movement device and a second deposition source which performs a second deposition process on the substrate after the first deposition process.

In an embodiment, a first region, in which the first deposition process is performed, and a second region, in which the second deposition process is performed, may be defined in the inner space of the chamber, and the second region may be adjacent to the first region in the first direction.

In an embodiment, the chamber may include a chamber inlet through which the substrate enters the inner space of the chamber, and the first region may be adjacent to the chamber inlet.

In an embodiment, the deposition apparatus may further include a barrier between the first region and the second region, and the barrier may include a first part and a second part.

In an embodiment, the second part may partially overlap the first region and the second region on a plane.

In an embodiment, the second part may move in a direction opposite to the first direction to overlap an entire portion of the first region on a plane to seal the first deposition source before the second deposition process is performed.

In an embodiment, the first deposition source may include a first target, the second deposition source may include a second target.

In an embodiment, the second target may include a plurality of second targets, and the first target may have a number less than a number of the second targets.

In an embodiment, the first target may have a rectangular cross-sectional shape, and the first target may be disposed to be inclined with respect to the substrate.

In an embodiment, the first deposition source may further include a first magnet and a shielding layer disposed between the first target and the first magnet.

In an embodiment, the second target may have a cylindrical shape extending in a second direction perpendicular to the first direction.

In an embodiment, the second deposition source may further include a rotary actuator that rotates the second target and a second magnet inside the second target.

In an embodiment, the deposition apparatus may further include a third deposition source which performs a third deposition process while the substrate is moved in the first direction by the movement device after the second deposition process.

In an embodiment, the deposition apparatus may further include a voltage application device which applies a power supply voltage to the first and second deposition sources.

In an embodiment, the deposition apparatus may further include a substrate holder which fixes the substrate onto the second deposition source.

According to an embodiment, a deposition method includes providing a deposition apparatus, where the deposition apparatus includes a chamber, a deposition source disposed in an inner space of the chamber and including a first deposition source and a second deposition source, a movement device which moves a substrate to which a deposition material is provided, and a substrate holder which fixes the substrate, loading the substrate into the inner space of the chamber through the movement device, performing a first deposition process using the first deposition source while the substrate moves in a first direction, fixing the substrate to the substrate holder disposed over the second deposition source, and performing a second deposition process using the second deposition source after the substrate is fixed to the substrate holder.

In an embodiment, the performing the first deposition process may include applying vacuum pressure to the inner space of the chamber, supplying a process gas into the inner space of the chamber, and applying a power supply voltage to the first deposition source.

In an embodiment, the deposition apparatus may further include a barrier disposed between the first deposition source and the second deposition source, and the deposition method may further include sealing the first deposition source using the barrier before the performing the second deposition process.

In an embodiment, a first deposition layer may be formed on the substrate by the first deposition process, a second deposition layer may be formed on the first deposition layer by the second deposition process, and the first deposition layer may be thinner than the second deposition layer.

In an embodiment, the deposition source may further include a third deposition source, and the deposition method may further include performing a third deposition process using the third deposition process source while the substrate moves in the first direction after the performing the second deposition.

### BRIEF DESCRIPTION OF THE DRAWINGS

The above and other features of embodiments of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a sectional view of a display module according to an embodiment of the present disclosure.

FIG. 4 is a sectional view of a display panel according to an embodiment of the present disclosure.

FIG. 5 is a sectional view of a deposition apparatus according to an embodiment of the present disclosure.

FIG. 6A is an enlarged view of a first deposition source of FIG. 5.

FIG. 6B is a perspective view illustrating a part of the deposition apparatus according to an embodiment of the present disclosure.

FIG. 7 is a sectional view illustrating a substrate according to an embodiment of the present disclosure.

FIG. 8A is a sectional view of a deposition apparatus according to an alternative embodiment of the present disclosure.

FIG. 8B is a sectional view of a deposition apparatus according to another alternative embodiment of the present disclosure.

FIG. 9 is a flowchart illustrating a deposition method using the deposition apparatus of FIG. 5 according to an embodiment of the present disclosure.

FIGS. 10A to 10E are views sequentially illustrating the deposition processes in FIG. 9 according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

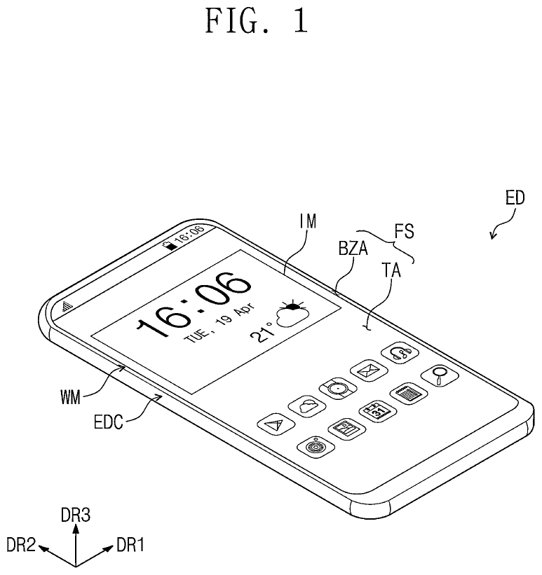

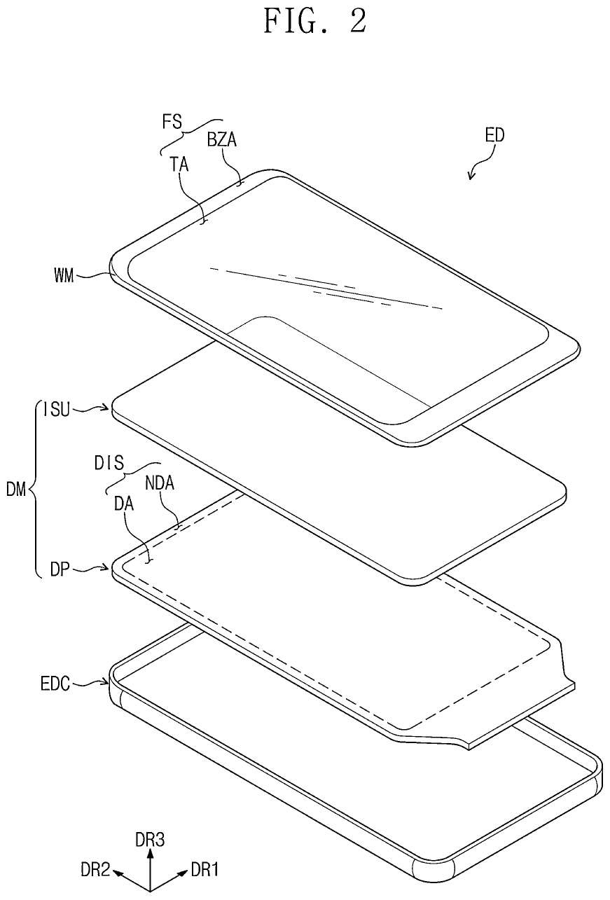

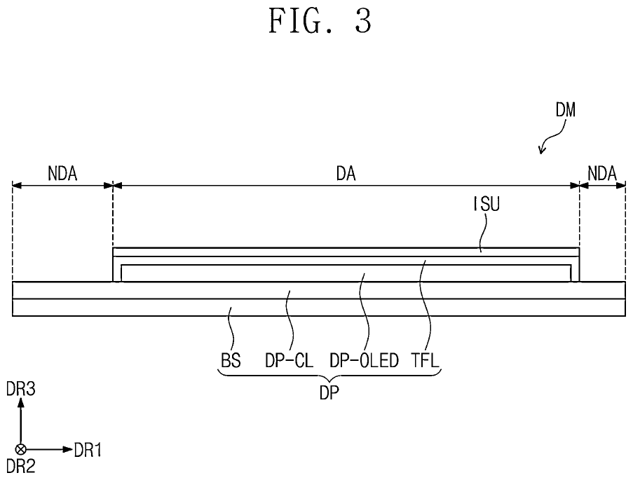

FIG. 1 is a perspective view of an electronic device according to an embodiment of the present disclosure. FIG. 2 is an exploded perspective view of the electronic device according to an embodiment of the present disclosure. FIG. 3 is a sectional view of a display module according to an embodiment of the present disclosure.

Referring to FIG. 1, an embodiment of the electronic device ED may be a device that is activated based on an electrical signal and that displays an image. In an embodiment, for example, the electronic device ED may be a large device such as a television, a billboard, or the like, or may be a small and medium-sized device such as a monitor, a mobile phone, a tablet computer, a car navigation unit, a game machine, or the like. In FIGS. 1 to 3, the embodiments of the electronic device ED are illustrative, and the electronic device ED is not limited to any one embodiment as long as it does not deviate from the spirit and scope of the present disclosure. In FIG. 1, an embodiment where the electronic device ED is a mobile phone is illustrated as an example.

In an embodiment, the electronic device ED may have a rectangular shape with short sides extending in a first direction DR1 and long sides extending in a second direction DR2 crossing the first direction DR1 on a plane or when viewed in a plan view (e.g., in a direction perpendicular to a plane defined by the first direction DR1 and the second direction DR2). Alternatively, without being limited thereto, the electronic device ED may have another one of various shapes, such as a circular shape, a polygonal shape, and the like, on the plane.

The electronic device ED according to an embodiment may include flexible characteristics. The term “flexible” used herein may refer to a property of being curved and may include everything from a structure that can be fully folded to a structure that can be curved to a level of several nanometers. In an embodiment, for example, the flexible electronic device ED may include a curved device or a foldable device. Alternatively, without being limited thereto, the electronic device ED includes rigid characteristics.

The electronic device ED may display an image IM in a third direction DR3 on a display surface parallel to the first direction DR1 and the second direction DR2. Here, the third direction DR3 may be a thickness direction of the electronic device ED. The image IM provided by the electronic device ED may include a still image as well as a dynamic image. In FIG. 1, an embodiment where the image IM includes a clock window and icons illustrated as examples.

The display surface on which the image IM is displayed, may correspond to a front surface of the electronic device ED. In FIG. 1, an embodiment where the display surface is a planar display surface is illustrated as an example. Alternatively, without being limited thereto, the display surface of the electronic device ED may include a curved surface bent from at least one side of a flat surface.

Front surfaces (or, upper surfaces) and rear surfaces (or, lower surfaces) of devices constituting the electronic device ED may be opposite each other in the third direction DR3, and the normal directions of the front surfaces and the rear surfaces may be substantially parallel to the third direction DR3. The separation distances between the front surfaces and the rear surfaces defined in the third direction DR3 may correspond to the thicknesses of the devices (or, units).

Referring to FIGS. 1 and 2, an embodiment of the electronic device ED may include a window WM, the display module DM, and a case EDC. The window WM may be coupled with the case EDC to form the exterior of the electronic device ED and may provide an inner space in which components of the electronic device ED are accommodated.

The window WM may be disposed on the display module DM. The window WM may have a shape corresponding to the shape of the display module DM. The window WM may cover the entire outside (or an outer surface) of the display module DM and may protect the display module DM from an external impact and a scratch.

The window WM may include an optically clear insulating material. In an embodiment, for example, the window WM may include a glass substrate or a polymer substrate. The window WM may have a single-layer structure or a multi-layer structure. The window WM may further include functional layers, such as an anti-fingerprint layer, a phase control layer, or a hard coating layer, which are disposed on a transparent substrate.

A front surface FS of the window WM may include a transmissive region TA and a bezel region BZA. The transmissive region TA of the window WM may be an optically clear region. The window WM may transmit, through the transmissive region TA, the image IM provided by the display module DM, and a user may visually recognize the corresponding image IM.

The bezel region BZA of the window WM may be provided as a region on which a material including a predetermined color is printed. The bezel region BZA of the window WM may prevent a component of the display module DM disposed to overlap the bezel region BZA from being visible from the outside.

The bezel region BZA may be adjacent to the transmissive region TA. The shape of the transmissive region TA may be substantially defined by the bezel region BZA. In an embodiment, for example, the bezel region BZA may be disposed around the transmissive region TA and may surround the transmissive region TA. However, this is illustrative, and the bezel region BZA may be disposed adjacent to only one side of the transmissive region TA, or may be omitted. Alternatively, the bezel region BZA may be disposed on an inside surface rather than the front surface of the electronic device ED.

The display module DM may be disposed between the window WM and the case EDC. The display module DM may include a display panel DP and an input sensor ISU.

The display panel DP may display the image IM in response to an electrical signal. The display panel DP according to an embodiment may be an emissive display panel, but is not particularly limited thereto. In an embodiment, for example, the display panel DP may be an organic light emitting display panel, an inorganic light emitting display panel, or a quantum dot light emitting display panel. An emissive layer of the organic light emitting display panel may include an organic light emitting material, and an emissive layer of the inorganic light emitting display panel may include an inorganic light emitting material. An emissive layer of the quantum dot light emitting display panel may include quantum dots and quantum rods. Hereinafter, for convenience of description, embodiments where the display panel DP is an organic light emitting display panel will be described in detail.

The image IM provided by the electronic device ED may be displayed on a front surface DIS of the display panel DP. The front surface DIS of the display panel DP may include a display region DA and a non-display region NDA. The display region DA may be a region that is activated based on an electrical signal and that displays the image IM. According to an embodiment, the display region DA of the display panel DP may correspond to the transmissive region TA of the window WM.

Herein, the expression “a region/portion corresponds to a region/portion” used herein means that “the regions/portions overlap each other”, but is not limited to having a same area and/or a same shape as each other.

The non-display region NDA may be adjacent to the outside of the display region DA. In an embodiment, for example, the non-display region NDA may surround the display region DA. Alternatively, without being limited thereto, the non-display region NDA may be defined in various shapes.

The non-display region NDA may be a region in which a drive circuit or drive wiring for driving elements disposed in the display region DA, various types of signal lines for providing electrical signals, and pads are disposed. The non-display region NDA of the display panel DP may correspond to the bezel region BZA of the window WM. The bezel region BZA may prevent components of the display panel DP disposed in the non-display region NDA from being visible from the outside.

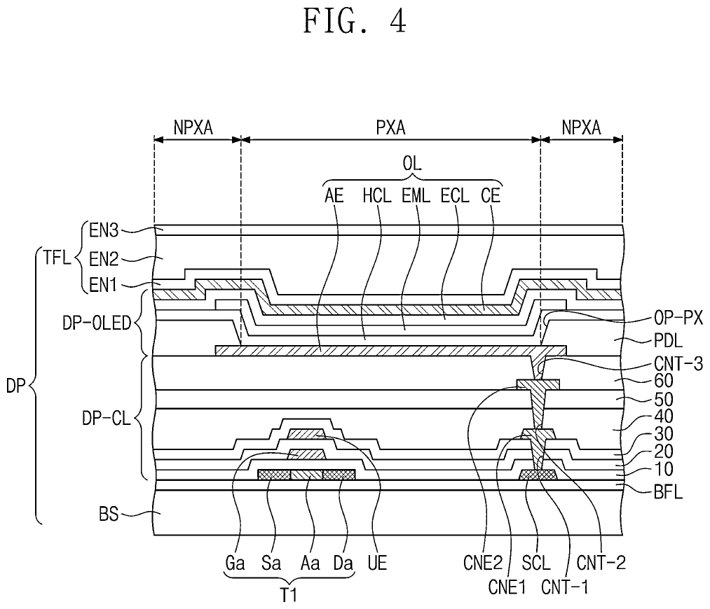

Referring to FIGS. 2 and 3, in an embodiment, the display panel DP may include a base layer BS, a circuit element layer DP-CL, a display element layer DP-OLED, and an encapsulation layer TFL. The display panel DP will be described below in detail with reference to FIG. 4.

The input sensor ISU may be disposed between the window WM and the display panel DP. The input sensor ISU may sense various forms of external inputs, such as force, pressure, temperature, light, or the like, which are provided from the outside. In an embodiment, for example, the input sensor ISU may sense contact by a part of the user's body or a pen that is provided from outside the electronic device ED, or an input (e.g., hovering) applied proximate to the electronic device ED.

The case EDC may be disposed under the display panel DP and may accommodate the display panel DP. The case EDC may include glass, plastic, or a metallic material that has a relatively high stiffness. The case EDC may protect the display panel DP by absorbing an impact applied from the outside or preventing infiltration of foreign matter/moisture into the display panel DP.

In an embodiment, the electronic device ED may further include an electronic module including various functional modules for operating the display panel DP and a power supply module for supplying power used for the electronic device ED. In an embodiment, for example, the electronic device ED may include a camera module as an example of the electronic module.

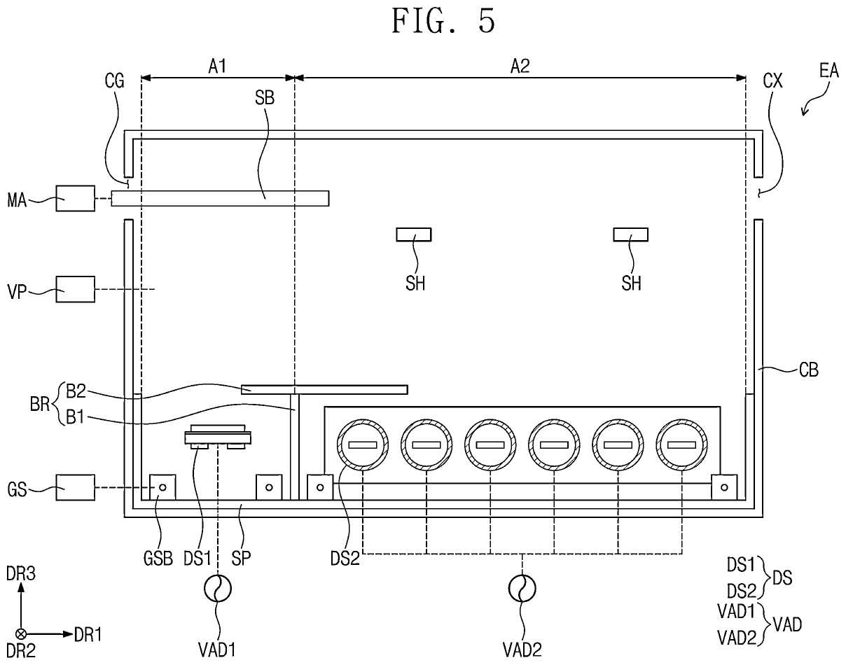

FIG. 4 is a sectional view of the display panel DP according to an embodiment of the present disclosure. A deposition apparatus EA (refer to FIG. 5) according to an embodiment of the present disclosure, which will be described below, may be used to form at least a part of functional layers included in the display panel DP. FIG. 4 illustrates a section of the display panel DP manufactured by using the deposition apparatus EA (refer to FIG. 5).

The display panel DP may include a plurality of pixels. Each of the pixels may include at least one transistor T1 and a light emitting element OL. FIG. 4 illustrates a region in which the transistor T1 and the light emitting element OL of one of the pixels of the display panel DP are disposed. Referring to FIG. 4, the display panel DP may include the base layer BS, the circuit element layer DP-CL, the display element layer DP-OLED, and the encapsulation layer TFL.

The base layer BS may provide a base surface on which the circuit element layer DP-CL is disposed. The base layer BS may include a synthetic resin film. The synthetic resin layer may be formed on a support substrate that is used in manufacture of the display panel DP, and thereafter a conductive layer and an insulating layer may be formed on the synthetic resin layer. Thereafter, the support substrate may be removed, and the synthetic resin layer from which the support substrate is removed may correspond to the base layer BS.

At least one inorganic layer may be disposed on an upper surface of the base layer BS. The inorganic layer may constitute a barrier layer and/or a buffer layer. FIG. 4 illustrates an embodiment where a buffer layer BFL is disposed on the base layer BS. The buffer layer BFL may improve a bonding force between the base layer BS and a semiconductor pattern of the circuit element layer DP-CL.

The circuit element layer DP-CL may be disposed on the buffer layer BFL. The circuit element layer DP-CL may include at least one insulating layer and a circuit element. The circuit element may include a signal line and a pixel drive circuit. The circuit element layer DP-CL may be formed through a process of forming an insulating layer, a semiconductor layer, and a conductive layer by coating, deposition, or the like and a process of making the insulating layer, the semiconductor layer, and the conductive layer subject to patterning by photolithography.

In an embodiment, the circuit element layer DP-CL may include the transistor T1, a connecting signal line SCL, connecting electrodes CNE1 and CNE2, and a plurality of insulating layers 10 to 60. The plurality of insulating layers 10 to 60 may include the first to sixth insulating layers 10 to 60 sequentially stacked on the buffer layer BFL. Each of the first to sixth insulating layers 10 to 60 may include one of an inorganic layer and an organic layer.

The transistor T1 may include a semiconductor pattern including a source region Sa, an active region Aa, and a drain region Da, and a gate electrode Ga. In an embodiment, the semiconductor pattern of the transistor T1 may include poly silicon. Alternatively, without being limited thereto, the semiconductor pattern may include amorphous silicon or metal oxide.

The semiconductor pattern may be divided into a plurality of regions depending on conductivities. In an embodiment, for example, the semiconductor pattern may have different electrical properties depending on whether doping is performed or whether metal oxide is reduced. A high-conductivity region in the semiconductor pattern may serve as an electrode or a signal line and may correspond to the source region Sa and the drain region Da of the transistor T1. A non-doped or non-reduced region having relatively low conductivity may correspond to the active region Aa (or, the channel region) of the transistor T1.

The connecting signal line SCL may be formed from (or defined by a portion of) the semiconductor pattern and may be disposed in (or directly on) a same layer as the source region Sa, the active region Aa, and the drain region Da of the transistor T1. According to an embodiment, the connecting signal line CSL may be electrically connected to the drain region Da of the transistor T1 on the plane.

The first insulating layer 10 may cover the semiconductor pattern of the circuit element layer DP-CL. The gate electrode Ga may be disposed on the first insulating layer 10. The gate electrode Ga may overlap the active region Aa on the plane. The gate electrode Ga may function as a mask in a process of doping the semiconductor pattern. An upper electrode UE may be disposed on the second insulating layer 20. The upper electrode UE may overlap the gate electrode Ga on the plane.

The first connecting electrode CNE1 and the second connecting electrode CNE2 may be disposed between the transistor T1 and the light emitting element OL and may electrically connect the transistor T1 and the light emitting element OL. The first connecting electrode CNE1 may be disposed on the third insulating layer 30 and may be connected to the connecting signal line SCL through a contact hole CNT-1 defined or formed through the first to third insulating layers 10 to 30. The second connecting electrode CNE2 may be disposed on the fifth insulating layer 50 and may be connected to the first connecting electrode CNE1 through a contact hole CNT-2 defined or formed through the fourth and fifth insulating layers 40 and 50.

The display element layer DP-OLED may be disposed on the circuit element layer DP-CL. The display element layer DP-OLED may include the light emitting element OLED and a pixel defining layer PDL. The light emitting element ED may include a first electrode AE, a second electrode CE, and an intermediate layer disposed between the first electrode AE and the second electrode CE. The first electrode AE and the second electrode CE may include or be formed of a conductive material. The intermediate layer may include at least one organic layer. In an embodiment, as shown in FIG. 4, the intermediate layer is illustrated as including a hole control layer HCL, an emissive layer EML, and an electron control layer ECL. However, this is illustrative, and the intermediate layer may further include an additional layer, in addition to the hole control layer HCL, the emissive layer EML, and the electron control layer ECL. Alternatively, at least one selected from the hole control layer HCL, the emissive layer EML, and the electron control layer ECL may be omitted, and the present disclosure is not limited to any one embodiment.

The first electrode AE and the pixel defining layer PDL may be disposed on the sixth insulating layer 60. The first electrode AE may be connected to the second connecting electrode CNE2 through a contact hole CNT-3 defined or formed through the sixth insulating layer 60. The pixel defining layer PDL may have a light emitting opening OP-PX defined therein through which at least a portion of the first electrode AE is exposed, and the portion of the first electrode AE exposed through the light emitting opening OP-PX may correspond to an emissive region PXA. The non-emissive region NPXA may surround the emissive region PXA.

The hole control layer HCL and the electron control layer ECL may be commonly disposed in the emissive region PXA and the non-emissive region NPXA. The emissive layer EML may be formed in a pattern form (or have a patterned shape) to correspond to the light emitting opening OP-PX. The emissive layer EML in a pattern form may be formed by using the deposition apparatus EA (refer to FIG. 5) according to an embodiment of the present disclosure.

Compared to the hole control layer HCL and the electron control layer ECL that have a film form, the emissive layer EML may be deposited in a different way. In an embodiment, for example, the hole control layer HCL and the electron control layer ECL may be commonly formed for the pixels by using a mask referred to as an open mask. The emissive layer EML may be differently formed depending on the pixels by using a mask referred to as a fine metal mask (FMM).

The encapsulation layer TFL may include a plurality of thin films. The encapsulation layer TFL according to an embodiment may include first to third thin films EN1, EN2, and EN3 sequentially stacked one above another. Each of the first to third thin films EN1, EN2, and EN3 may include one of an inorganic film and an organic film. The inorganic film may protect the light emitting element OL from moisture and/or oxygen. The organic film may protect the light emitting element OL from foreign matter such as dust particles. However, a configuration of the encapsulation layer TFL is not limited to that illustrated in the drawing as long as the encapsulation layer TFL is capable of protecting the light emitting element OL or improving light emission efficiency.

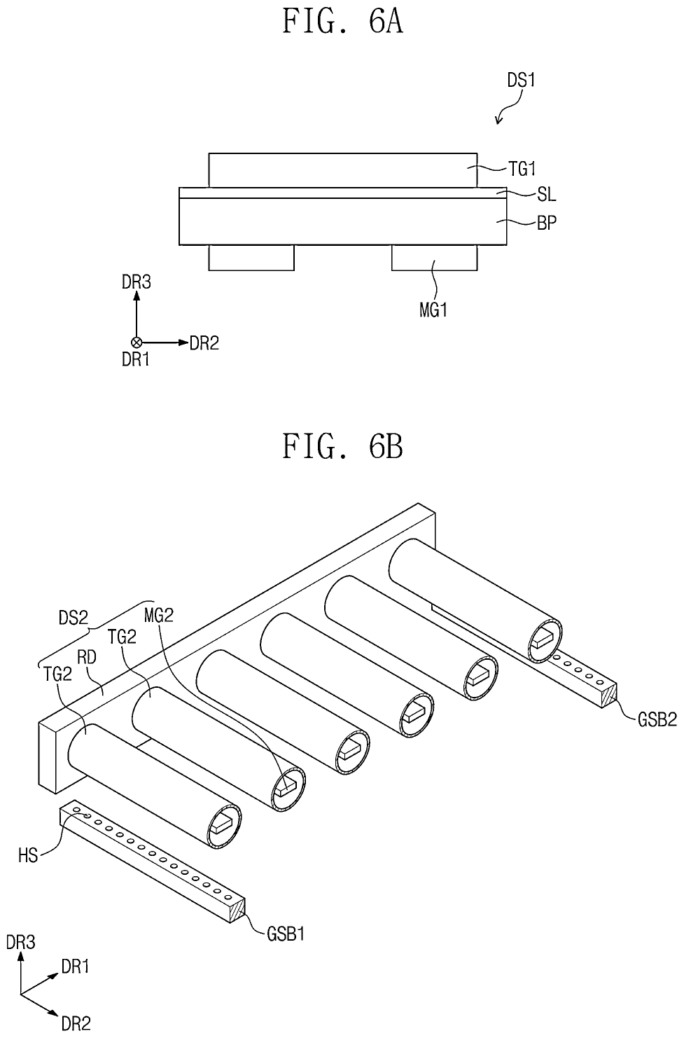

FIG. 5 is a sectional view of the deposition apparatus according to an embodiment of the present disclosure. FIG. 6A is an enlarged view of a first deposition source of FIG. 5. FIG. 6B is a perspective view illustrating a part of the deposition apparatus according to an embodiment of the present disclosure.

Referring to FIG. 5, the deposition apparatus EA according to an embodiment of the present disclosure may perform deposition using a sputtering method. An embodiment of the deposition apparatus EA may include a chamber CB, a movement device MA that moves a substrate SB, and a deposition source DS that provides a deposition material to the substrate SB.

The chamber CB may have an inner space defined therein. The inner space may be a sealed space. The inner space may be set to a vacuum state when a deposition process is performed. The substrate SB and the deposition source DS may be disposed in the inner space of the chamber CB. A sputtering deposition process may be performed on the substrate SB in the inner space of the chamber CB. The chamber CB may include at least one chamber inlet CG. The chamber CB may be opened and closed through the chamber inlet CG. The substrate SB may enter the chamber CB through the chamber inlet CG included in the chamber CB. Although not illustrated, a mask, a mask frame, and a stage unit may also enter the chamber CB through the chamber inlet CG included in the chamber CB. The chamber CB may include at least one chamber outlet CX, and the substrate SB may move out of the chamber CB through the chamber outlet CX.

The chamber CB may include a bottom wall, a top wall, and sidewalls. The bottom wall of the chamber CB may be parallel to a plane defined by the first direction DR1 and the second direction DR2, and the normal direction of the bottom wall of the chamber CB may be parallel to the third direction DR3. In this specification, “on a plane” is set based on a plane parallel to the plane defined by the first direction DR1 and the second direction DR2.

The movement device MA may move the substrate SB. In an embodiment, the movement device MA may move the substrate SB in the first direction DR1. In such an embodiment, the movement device MA may include an actuator such as an electric motor or a hydraulic motor. Without being limited thereto, the movement device MA may be coupled to a substrate holder SH and may move the substrate holder SH. In an embodiment, as illustrated in FIG. 5, the movement device MA may be located outside the chamber CB, but is not limited thereto.

A vacuum pump VP may be disposed outside the chamber CB. The vacuum pump VP may be connected to the chamber CB from outside the chamber CB. The vacuum pump VP may provide vacuum pressure into the inner space of the chamber CB. The inner space of the chamber CB may be maintained in a state close to vacuum during a process by the vacuum pump VP.

The substrate SB may be an object to which the deposition material is provided by the deposition source DS in the inner space of the chamber CB. The substrate SB may have a surface on a plane defined by the first direction DR1 and the second direction DR2 crossing the first direction DR1. The material deposited onto the substrate SB will be described below.

According to an embodiment of the present disclosure, the deposition source DS may include the first deposition source DS1 and a second deposition source DS2. The first deposition source DS1 may be disposed adjacent to the chamber inlet CG, and the second deposition source DS2 may be disposed adjacent to the chamber outlet CX. The first deposition source DS1 and the second deposition source DS2 may be divided or separated from each other by a barrier BR disposed between the first deposition source DS1 and the second deposition source DS2.

The first deposition source DS1 may be disposed in a direction facing the substrate SB. In an embodiment, a first target TG1 (refer to FIG. 6A) may be disposed toward the substrate SB in the third direction DR3. Accordingly, the deposition material may be deposited onto the substrate SB by the first target TG1 while the substrate SB moves in the first direction DR1 in the inner space of the chamber CB.

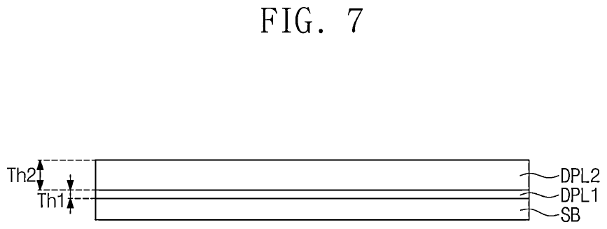

A first deposition process of forming a first deposition layer DPL1 (refer to FIG. 7) on the substrate SB may be performed by the first deposition source DS1. A region in which the first deposition process is performed by the first deposition source DS1 may be defined as a first region A1. Since the first deposition process is performed while the substrate SB enters the chamber inlet CG, the first region A1 may be adjacent to the chamber inlet CG. A second deposition process of forming a second deposition layer DPL2 (refer to FIG. 7) on the substrate SB may be performed by the second deposition source DS2. A region in which the second deposition process is performed by the second deposition source DS2 may be defined as a second region A2. In an embodiment of the present disclosure, since the second deposition layer DPL2 is formed on the first deposition layer DPL1, the substrate SB on which the first deposition process is completely performed in the first region A1 may enter the second region A2.

The first region A1 and the second region A2 may be adjacent to each other in the first direction DR1. The first region A1 and the second region A2 may be divided or separated from each other by the barrier BR disposed between the first region A1 and the second region A2. According to an embodiment of the present disclosure, the barrier BR may be disposed to partially overlap the first region A1 and the second region A2 on the plane. In an embodiment, for example, the barrier BR may include a first part B1 extending from a support part SP in the third direction DR3 and a second part B2 extending in a direction parallel to the first direction DR1 from a point spaced apart from the first deposition source DS1 and the second deposition source DS2 in the third direction DR3. The second part B2 may be disposed to partially overlap the first region A1 and the second region A2 on the plane. Since the second part B2 partially overlaps the first region A1 and the second region A2 on the plane, contamination and influence caused by the second deposition source DS2 may be reduced when the first deposition process is performed, and contamination and influence caused by the first deposition source DS1 may be reduced when the second deposition process is performed. According to an embodiment of the present disclosure, before the second deposition process is performed, the second part B2 may move in the direction opposite to the first direction DR1 to overlap the entire first region A1 to seal the first deposition source DS1. In such an embodiment, the second part B2 may move in the direction opposite to the first direction DR1 and may make contact with an outer wall of the chamber CB. Since the second part B2 of the barrier BR makes contact with the outer wall of the chamber CB, the first deposition source DS1 may be sealed by the support part SP and the second part B2 of the barrier BR. The barrier BR may be a structure for reducing interference between the first deposition and the second deposition during the deposition process and may include a hard metal. In an embodiment, for example, the barrier BR may include or be formed of a metallic material such as iron (Fe), nickel (Ni), or cobalt (Co).

The deposition apparatus EA may further include a gas supply bar GSB disposed in the inner space of the chamber CB. The gas supply bar GSB may spray a process gas into the inner space of the chamber CB. The gas supply bar GSB may be connected to a gas supply unit GS. The process gas supplied from the gas supply unit GS may be dispersed through the gas supply bar GSB and may be sprayed into the inner space of the chamber CB. The gas supply bar GSB may be disposed adjacent to the first deposition source DS1 and the second deposition source DS2. In an embodiment, as illustrated in FIG. 5, the gas supply bar GSB may be provided in plural, that is, a plurality of gas supply bars GSB may be provided. Alternatively, without being limited thereto, only one gas supply bar GSB may be provided in the inner space of the chamber CB.

The support part SP may support the gas supply bar GSB, the first deposition source DS1, and the second deposition source DS2. The gas supply bar GSB, the first deposition source DS1, and the second deposition source DS2 may be fixed in predetermined positions in the chamber CB by the support part SP.

A voltage application device VAD may provide or apply power supply voltages to the first deposition source DS1 and the second deposition source DS2. The voltage application device VAD may include a first voltage application device VAD1 and a second voltage application device VAD2. The first voltage application device VAD1 may apply a first power supply voltage to the first target TG1, and the second voltage application device VAD2 may apply a second power supply voltage to a second target TG2 (refer to FIG. 6B). According to an embodiment of the present disclosure, the first power supply voltage and the second power supply voltage may be alternating current (AC) voltages that swing at different amplitudes. In an embodiment, the amplitude of the second power supply voltage may be greater than the amplitude of the first power supply voltage.

According to an embodiment of the present disclosure, the deposition apparatus EA may further include the substrate holder SH in the inner space of the chamber CB. The substrate holder SH may support the substrate SB when in a position over the second deposition source DS2. In an embodiment, for example, when the deposition process is performed using the deposition apparatus EA, the substrate holder SH may support the substrate SB over the second deposition source DS2. In an embodiment, without being limited thereto, the substrate holder SH may move the substrate SB. More specifically, the substrate holder SH may move the substrate SB by moving in a horizontal direction (e.g., the first direction DR1) while supporting the substrate SB. The substrate holder SH may be spaced apart upward from the second deposition source DS2. In an embodiment, the substrate holder SH may be located on the opposite side to the gas supply bar GSB with respect to the second target TG2.

Referring to FIGS. 5 and 6A, in an embodiment, the first deposition source DS1 may include the first target TG1, a shielding layer SL, a support plate BP, and a first magnet MG1.

The first target TG1 may be disposed adjacent to the substrate SB. In an embodiment, the first target TG1 may be disposed to face the substrate SB in the vertical direction of the substrate SB, that is, the third direction DR3. According to an embodiment of the present disclosure, the first target TG1 may have a rectangular cross-section. Alternatively, without being limited thereto, the first target TG1 may have a polygonal or circular cross-section. The first target TG1 may include a target material. According to an embodiment of the present disclosure, the second target TG2 may include a target material different from that of the first target TG1. In an embodiment, for example, the first target TG1 may include titanium (Ti) as a target material. In such an embodiment, titanium (Ti) may be deposited onto the substrate SB. alternatively, without being limited thereto, the first target TG1 may include at least one selected from aluminum (A1), silicon (Si), tantalum (Ta), and zinc (Zn).

The first magnet MG1 may be disposed under the first target TG1. In an embodiment, the first magnet MG1 may be the lowermost component of the first deposition source DS1 in the direction opposite to the third direction DR3 with respect to the first target TG1. The first magnet MG1 may control the position of an ionized fluid. The first voltage application device VAD1 may apply the first power supply voltage to the first deposition source DS1 to generate plasma between the substrate SB and the first target TG1. The first magnet MG1 may apply a magnetic field to prevent electrons generated from the plasma from escaping to other portions of the inner space of the chamber CB. Accordingly, when the first deposition process is performed, the first magnet MG1 may make an adjustment such that the deposition material is deposited onto the substrate SB on a desired position. According to an embodiment of the present disclosure, the first magnet MG1 may be an electromagnet. The first magnet MG1 may increase the concentration of the plasma generated between the substrate SB and the first target TG1, thereby increasing deposition efficiency.

In an embodiment, the shielding layer SL may be disposed under the first target TG1 and between the first target TG1 and the support plate BP. The shielding layer SL may be a layer for adjusting the amount of the deposition material deposited onto the substrate SB while the first deposition process is performed. The shielding layer SL may serve to lower the concentration of the plasma generated between the substrate SB and the first target TG1. Accordingly, the amount of the deposition material deposited during the first deposition process may be reduced due to a decrease in the concentration of the plasma. The shielding layer SL may include or be formed of a ferromagnetic material. In an embodiment, for example, the shielding layer SL may include or be formed of a metallic material such as iron (Fe), nickel (Ni), or cobalt (Co).

The support plate BP may be disposed under the shielding layer SL. The support plate BP may be a plate supporting the first target TG1 and may include or be formed of a hard metal. The first target TG1 and the shielding layer SL may be fixed in a predetermined position in the chamber CB by the support plate BP.

Referring to FIGS. 5 and 6B, the second deposition source DS2 may include the second target TG2, a second magnet MG2, and a rotary actuator RD. The second target TG2 may include a target material. In an embodiment, for example, the second target TG2 may include copper (Cu) as a target material. In such an embodiment, copper (Cu) may be deposited onto the substrate SB through the second deposition process. Alternatively, without being limited thereto, the second target TG2 may include at least one selected from titanium (Ti), aluminum (A1), silicon (Si), tantalum (Ta), and zinc (Zn). The rotary actuator RD may be coupled to one end of the second target TG2 and may rotate the second target TG2. In an embodiment, the rotary actuator RD may be located in the inner space of the chamber CB. Alternatively, without being limited thereto, the rotary actuator RD may be disposed outside the chamber CB.

The second target TG2 may have a cylindrical (or cylindrical pipe) shape extending in the second direction DR2. The second target TG2 may rotate. In an embodiment, for example, the second target TG2 may be rotated in place about an axis parallel to the second direction DR2 by the rotary actuator RD. Alternatively, the rotary actuator RD may be connected to opposite ends of the second target TG2. The rotary actuator RD may include an actuator such as an electric motor or a hydraulic motor.

The gas supply unit GS may be disposed outside the chamber CB. The gas supply unit GS may supply the process gas into the chamber CB. In an embodiment, the gas supply unit GS may spray the process gas into the inner space of the chamber CB through the gas supply bar GSB. In such an embodiment, the gas supply unit GS may include a gas tank, a gas passage, and a gas valve. The gas supply unit GS may supply various types of process gases. In an embodiment, for example, the gas supply unit GS may store and supply oxygen (O₂), nitrogen (N₂), and/or argon (Ar). Alternatively, without being limited thereto, the gas supply unit GS may supply other types of process gases.

In an embodiment of the present disclosure, the gas supply bar GSB may include a first gas supply bar GSB1 and a second gas supply bar GSB2.

The first and second gas supply bars GSB1 and GSB2 may extend in a same direction as the second target TG2. In such an embodiment, the first and second gas supply bars GSB1 and GSB2 may extend in the second direction DR2. Each of the first and second gas supply bars GSB1 and GSB2 may be provided with a plurality of spray holes Hs defined therein. The plurality of spray holes Hs may be spaced apart from each other in the second direction DR2.

The second gas supply bar GSB2 may be spaced apart from the first gas supply bar GSB1 in the first direction DR1. The first and second gas supply bars GSB1 and GSB2 may include substantially the same or similar configuration as each other.

The second magnet MG2 may be provided inside the second target TG2. A plurality of second targets TG2 may be provided. Accordingly, a plurality of second magnets MG2 may be provided to correspond to the plurality of second targets TG2. The second magnet MG2 may control the position of an ionized fluid. The second voltage application device VAD2 may apply the second power supply voltage to the second deposition source DS2 to generate plasma between the substrate SB and the second target TG2. The second magnet MG2 may apply a magnetic field to prevent electrons generated from the plasma from escaping to other portions of the inner space of the chamber CB. Accordingly, when the second deposition process is performed, the second magnet MG2 may make an adjustment such that the deposition material is deposited onto the substrate SB on a desired position. In an embodiment, the second power supply voltage may be applied to the second deposition source DS2 by the second voltage application device VAD2, and when the second power supply voltage is applied to the second magnet MG2, the deposition material may be intensively deposited onto the substrate SB depending on the position of the second magnet MG2. According to an embodiment of the present disclosure, the second magnet MG2 may be an electromagnet. The second magnet MG2 may increase the concentration of the plasma generated between the substrate SB and the second target TG2, thereby increasing deposition efficiency.

Referring to FIGS. 5 to 6B, the number of first targets TG1 included in the first deposition source DS1 may differ from the number of second targets TG2 included in the second deposition source DS2. In an embodiment, the number of first targets TG1 may be less than the number of second targets TG2. Since the first deposition process performed by the first deposition source DS1 aims at depositing the first deposition layer DPL1 on the substrate SB to a thickness less than that of the second deposition layer DPL2, the number of first targets TG1 may be smaller than the number of second targets TG2. In an embodiment, for example, the number of first targets TG1 may be one, and the number of second targets TG2 may be in a range from 8 to 12.

FIG. 7 is a sectional view illustrating the substrate according to an embodiment of the present disclosure. Specifically, FIG. 7 is a sectional view illustrating the substrate SB after the first and second deposition processes are performed.

Referring to FIG. 7, the first deposition layer DPL1 may be disposed on the substrate SB, and the second deposition layer DPL2 may be disposed on the first deposition layer DPL1. The first deposition layer DPL1 is a layer formed by the first deposition process, and the second deposition layer DPL2 is a layer formed by the second deposition process. According to an embodiment of the present disclosure, the first deposition layer DPL1 and the second deposition layer DPL2 may be used as some components of the connecting signal line SCL, the connecting electrodes CNE1 and CNE2, the gate electrode Ga, and the upper electrode UE included in the circuit element layer DP-CL and the first electrode AE and the second electrode CE included in the display element layer DP-OLED illustrated in FIG. 4. Alternatively, without being limited thereto, the first deposition layer DPL1 and the second deposition layer DPL2 may be used as components of electrodes disposed in a non-illustrated input sensing layer.

The thickness Th1 of the first deposition layer DPL1 and the thickness Th2 of the second deposition layer DPL2 may differ from each other. According to an embodiment of the present disclosure, the thickness Th1 of the first deposition layer DPL1 may be less than the thickness Th2 of the second deposition layer DPL2. In an embodiment, the thickness Th1 of the first deposition layer DPL1 may be in range from about 10 angstrom (Å) to about 30 Å. Since the thickness Th1 of the first deposition layer DPL1 is about 30 Å or less, the consumption of the first target TG1 (refer to FIG. 5) used in the first deposition process may be reduced. In such an embodiment, where the first deposition layer DPL1 is thin, the etching time of the first deposition layer DPL1 may be decreased, and thus over-etching of the second deposition layer DPL2, which is simultaneously etched together with the first deposition layer DPL1, may be improved. Accordingly, the reliable display panel DP (refer to FIG. 4) may be provided.

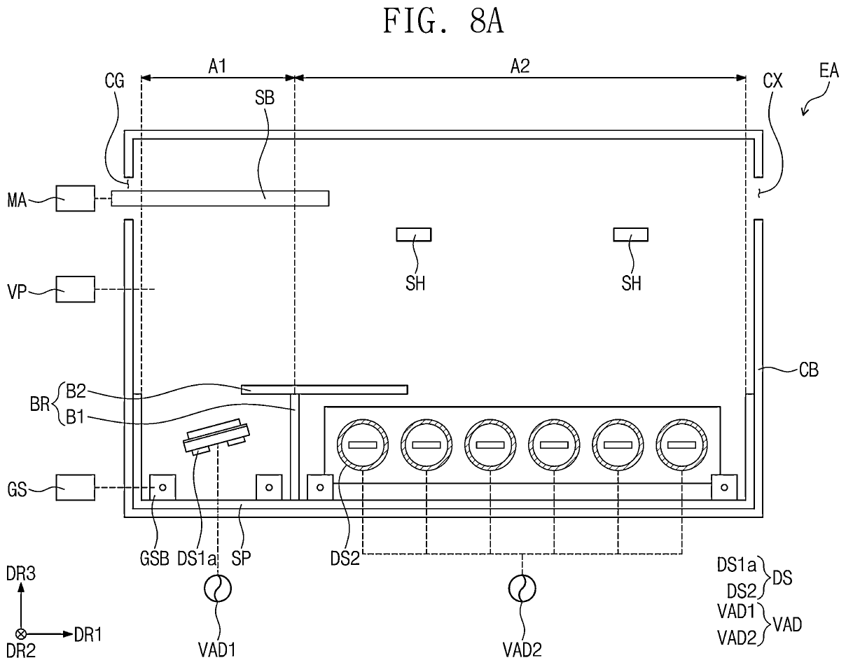

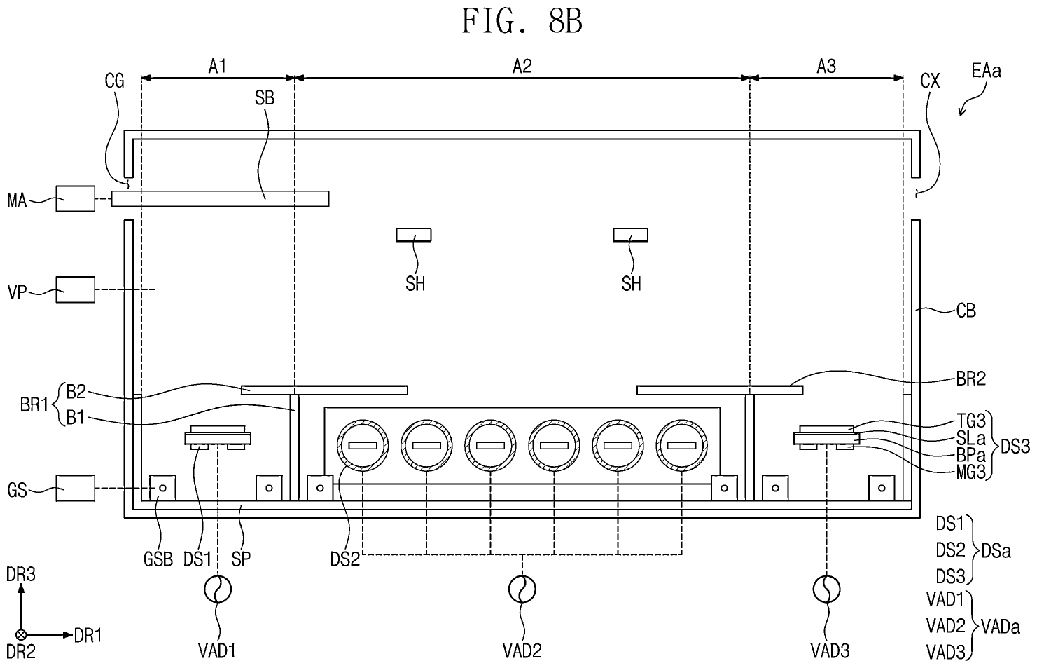

FIG. 8A is a sectional view of a deposition apparatus according to an alternative embodiment of the present disclosure.

According to an embodiment of the present disclosure, a first deposition source DS1a may be disposed to be inclined with respect to a substrate SB. In such an embodiment, a first target TG1 (refer to FIG. 6A) may be disposed to be inclined at a predetermined angle toward a chamber inlet CG with respect to the substrate SB.

A first deposition layer DPL1 (refer to FIG. 7) may be formed by the first deposition source DS1a while the substrate SB moves in the first direction DR1. Since the first deposition source DS1a is disposed to be inclined at the predetermined angle toward the chamber inlet CG with respect to the substrate SB, a deposition material formed from the first deposition source DS1a may be less affected by a barrier BR.

FIG. 8B is a sectional view of a deposition apparatus according to another alternative embodiment of the present disclosure. Referring to FIG. 8B, an embodiment of the deposition apparatus EAa may include a chamber CB, a movement device MA that moves a substrate SB, and a deposition source DSa that provides a deposition material to the substrate SB. The deposition source DSa may include a first deposition source DS1, a second deposition source DS2, and a third deposition source DS3. The third deposition source DS3 may perform a third deposition process while the substrate SB is moved in the first direction DR1 by the movement device MA after a second deposition process. A region in which the third deposition process is performed may be defined as a third region A3. The first deposition source DS1 and the second deposition source DS2 are the same as those described above with reference to FIG. 5, and therefore any repetitive detailed descriptions thereof will be omitted.

The third deposition source DS3 may be disposed adjacent to a chamber outlet CX. In an embodiment, although not illustrated, the third deposition source DS3 may be disposed to be inclined with respect to the third direction DR3. In such an embodiment, a third target TG3 may be disposed to be inclined at a predetermined angle toward the chamber outlet CX with respect to the third direction DR3.

A first region A1 and a second region A2 may be divided or separated from each other by a first barrier BR1 disposed between the first region A1 and the second region A2, and the second region A2 and the third region A3 may be divided or separated from each other by a second barrier BR2 disposed between the second region A2 and the third region A3. According to an embodiment of the present disclosure, the second barrier BR2 may be disposed to partially overlap the second region A2 and the third region A3 on the plane. In an embodiment, the second barrier BR2 may have a structure that extends in the third direction DR3 and extends in a direction parallel to the first direction DR1 from a point spaced apart from the second deposition source DS2 and the third deposition source DS3 in the third direction DR3. Since the structure of the second barrier BR2 extending parallel to the first direction DR1 partially overlaps the second region A2 and the third region A3 on the plane, contamination and influence caused by the third deposition source DS3 may be reduced when the second deposition process is performed, and contamination and influence caused by the second deposition source DS2 may be reduced when the third deposition process is performed.

The third deposition source DS3 may include a configuration that is substantially the same as or similar to that of the first deposition source DS1. That is, the third deposition source DS3 may include the third target TG3, a shielding layer SLa, a support plate BPa, and a third magnet MG3. In an embodiment, the third target TG3 may include titanium (Ti) as a target material. In such an embodiment, titanium (Ti) may be deposited onto the substrate SB.

A voltage application device VADa may apply power supply voltages to the first deposition source DS1, the second deposition source DS2, and the third deposition source DS3. The voltage application device VADa may include a first voltage application device VAD1, a second voltage application device VAD2, and a third voltage application device VAD3. The third voltage application device VAD3 may apply a third power supply voltage to the third target TG3, and the third power supply voltage may be an AC voltage. The amplitude of the third power supply voltage applied to the third target TG3 may be the same as the amplitude of a first power supply voltage applied to a first target TG1.

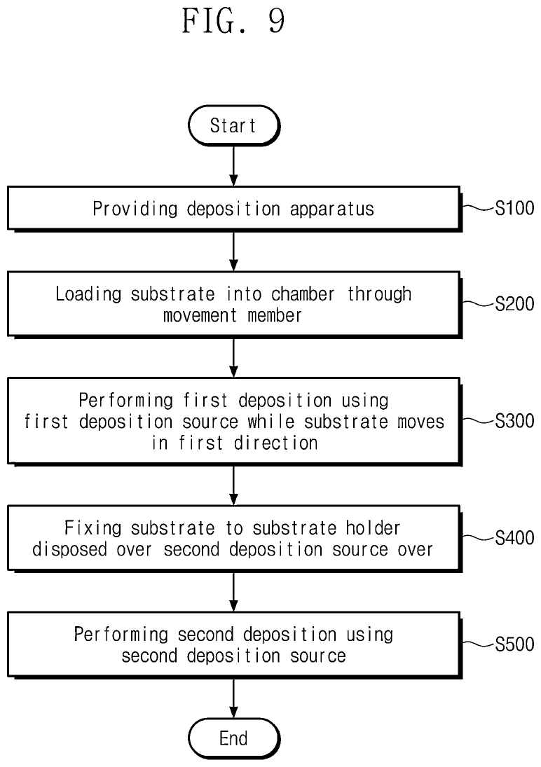

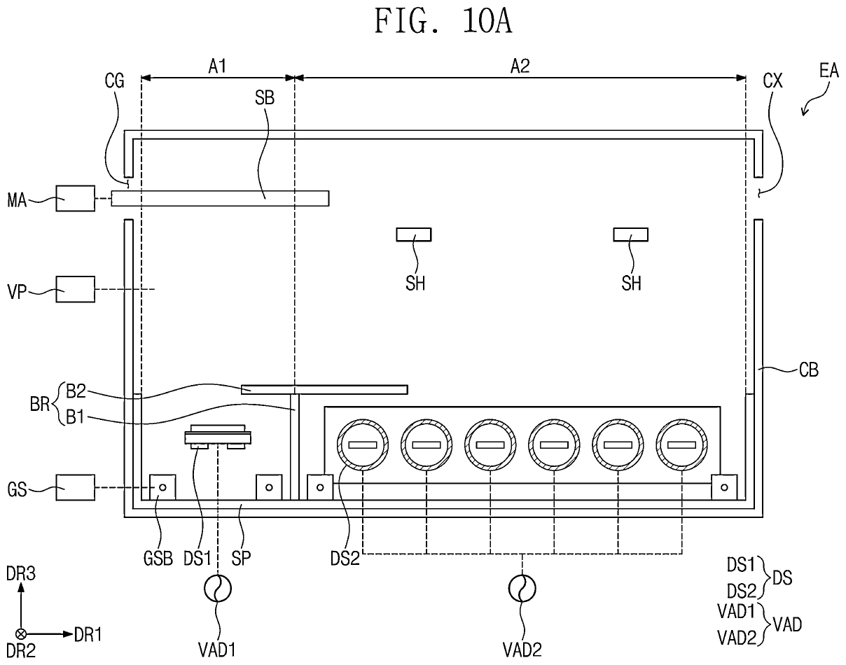

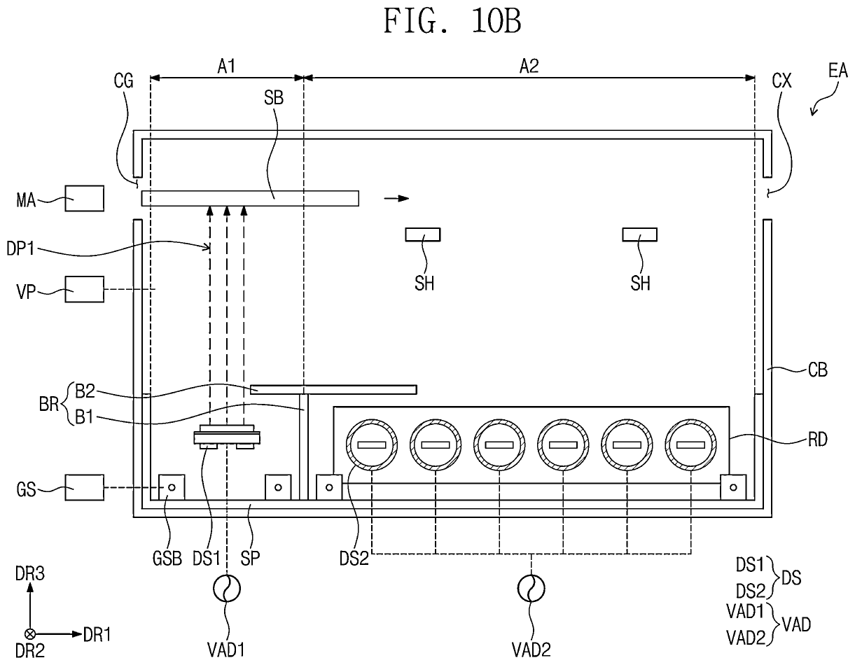

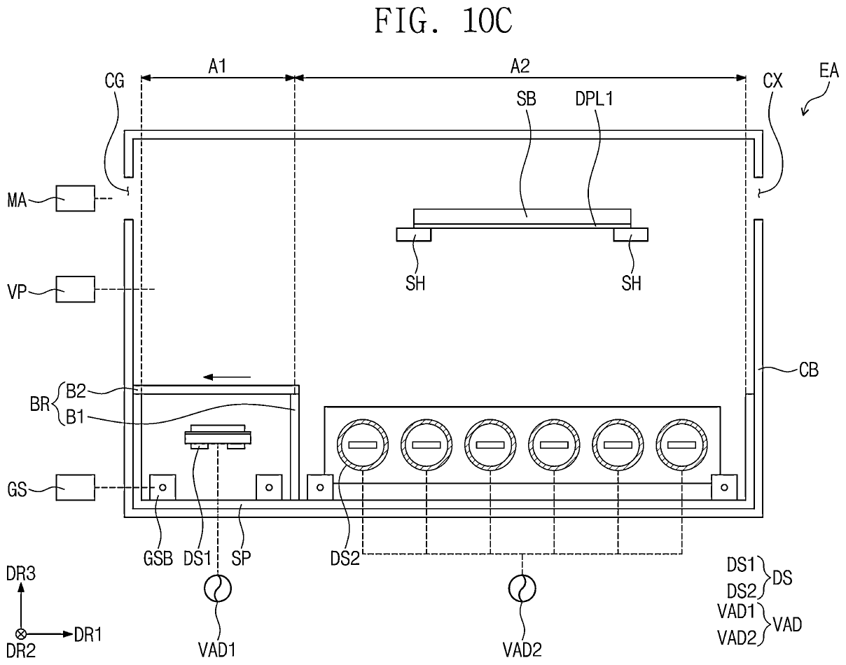

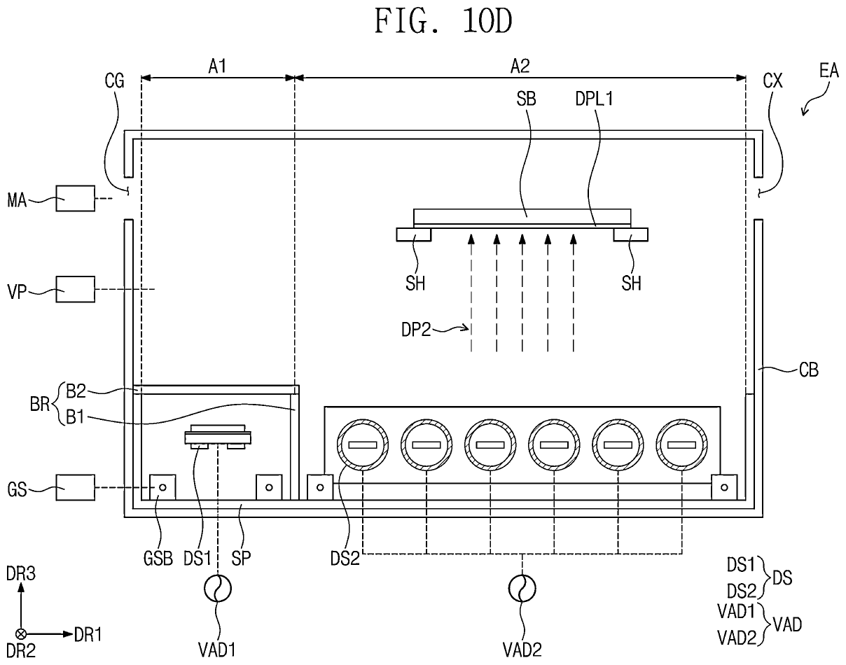

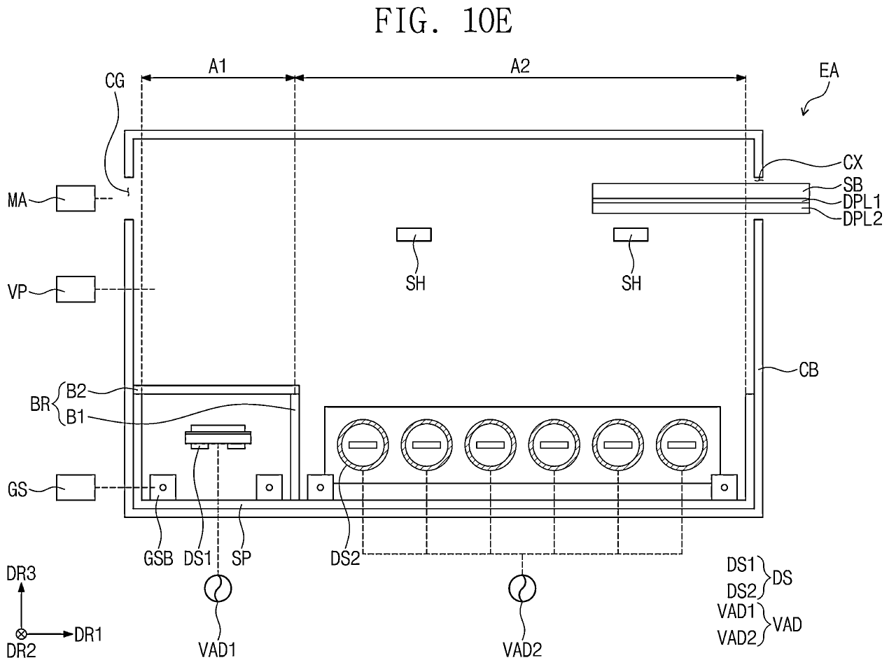

FIG. 9 is a flowchart illustrating a deposition method using the deposition apparatus of FIG. 5 according to an embodiment of the present disclosure. FIGS. 10A to 10E are views sequentially illustrating deposition processes in FIG. 9 according to an embodiment of the present disclosure.

Referring to FIG. 9, an embodiment of the deposition method may use the deposition apparatus EA (refer to FIG. 10A). The deposition method may include a process S100 of providing (or preparing) the deposition apparatus, a process S200 of loading a substrate into the chamber through the movement device, a process S300 of performing the first deposition process using the first deposition source while the substrate moves in the first direction, a process S400 of fixing the substrate to the substrate holder disposed over the second deposition source, and a process S500 of performing the second deposition process using the second deposition source. In an alternative embodiment, the deposition method may further include a process of performing the third deposition process using the third deposition source while the substrate moves in the first direction after the second deposition process.

In an embodiment, the process of performing the first deposition process may include a process of applying vacuum pressure to the inner space of the chamber, a process of supplying the process gas into the inner space of the chamber, and a process of applying the first power supply voltage to the first deposition source. In an embodiment, the process of performing the first deposition process may further include a process of sealing the first deposition source using the barrier before the process of performing the second deposition process.

Hereinafter, an embodiment of the deposition method of FIG. 9 will be described in detail with reference to FIGS. 10A to 10E.

Referring to FIGS. 9 and 10A, the process S100 of providing the deposition apparatus EA may be performed. The deposition apparatus EA may include the chamber CB, the deposition source DS including the first deposition source DS1 and the second deposition source DS2 that are disposed in the inner space of the chamber CB, the movement device MA that moves the substrate SB onto which the deposition material is deposited, the barrier BR disposed between the first deposition source DS1 and the second deposition source DS2, and the substrate holder SH that fixes the substrate SB.

The process S200 of loading the substrate SB into the inner space of the chamber CB through the movement device MA disposed outside the chamber CB of the provided deposition apparatus EA may be performed. In an embodiment, the substrate SB may enter the inner space of the chamber CB through the chamber inlet CG of the chamber CB. The substrate SB may move in a horizontal direction, that is, in the first direction DR1 in the inner space of the chamber CB. According to an embodiment, the movement device MA may directly move the substrate SB. Alternatively, without being limited thereto, the movement device MA may move the substrate holder SH to which the substrate SB fixed to move the substrate SB.

Referring to FIGS. 9 and 10B, the first deposition process DP1 may be performed by the first deposition source DS1 while the substrate SB moves in the first direction DR1 (S300). The first deposition process DP1 may be performed after the substrate SB enters the chamber inlet CG. The first deposition process DP1 may include a process of closing the chamber inlet CG and applying vacuum pressure to the inner space of the chamber CB, a process of supplying the process gas into the inner space of the chamber CB, and a process of applying the first power supply voltage to the first deposition source DS1.

The process of applying the vacuum pressure to the inner space of the chamber CB may be performed by the vacuum pump VP disposed outside the chamber CB. The inner space of the chamber CB may be maintained in a state close to vacuum during the process by the vacuum pump VP. For a smooth or effective deposition process, a high-vacuum state may be formed in the inner space of the chamber CB by the vacuum pump VP.

In the process of supplying the process gas into the inner space of the chamber CB, the gas supply bar GSB may spray the process gas into the inner space of the chamber CB. The process gas supplied from the gas supply unit GS disposed outside the chamber CB may be dispersed through the gas supply bar GSB and may be sprayed into the inner space of the chamber CB. The gas supply unit GS may be disposed outside the deposition chamber CB. The process gas may be an inert gas. In an embodiment, for example, the inert gas may be argon (Ar) gas, but is not limited thereto. The inert gas may be formed into plasma and may be used to separate particles constituting the first target TG1.

In the process of applying the first power supply voltage to the first deposition source DS1, the first voltage application device VAD1 may apply the first power supply voltage to the first deposition source DS1 to generate plasma between the substrate SB and the first target TG1. The inert gas may be formed into plasma and may collide with the first target TG1 to separate the particles constituting the first target TG1, and the separated particles may be deposited onto the substrate SB to form the first deposition layer DPL1 (refer to FIG. 10C).

The first deposition layer DPL1 may be formed by the first deposition process DP1 while the substrate SB moves in the first direction DR1. In an embodiment, although not illustrated, the first deposition source DS1 may be disposed to be inclined at a predetermined angle toward the chamber inlet CG with respect to the substrate SB, and thus the deposition material formed from the first deposition source DS1 may be less affected by the barrier BR. Since the first deposition layer DPL1 is formed by the first deposition process DP1 while the substrate SB moves in the first direction DR1, the first deposition process DP1 may be evenly performed on the substrate SB, and thus the flatness of the first deposition layer DPL1 may be increased, as compared with when the deposition is performed in a state in which the substrate SB is fixed. In addition, by reducing the deposition time, the first deposition layer DPL1 may be formed to be thin. In an embodiment, the first deposition layer DPL1 may have a thickness in a range of about 10 Å to about 30 Å.

Referring to FIGS. 9 and 10C, the process S400 of fixing the substrate SB to the substrate holder SH disposed over the second deposition source DS2 may be performed. To correspond to the second deposition source DS2, the substrate holder SH may be disposed in the region in which the second deposition process DP2 (refer to FIG. 10D) is performed. The substrate SB on which the first deposition process DP1 is completely performed may be fixedly disposed on the substrate holder SH. In an embodiment, although not illustrated, a mask may be disposed on the substrate holder SH before the substrate SB is disposed on the substrate holder SH.

A process of stopping, by the first voltage application device VAD1, the first power supply voltage applied to the first deposition source DS1 may be performed after the process S300 of performing the first deposition process DP1. Since the application of the first power supply voltage to the first deposition source DS1 is stopped by the first voltage application device VAD1, the first deposition process DP1 may be stopped.

The process of sealing the first deposition source DS1 using the barrier BR may be performed before the process S500 of performing the second deposition process. The barrier BR may include the first part B1 extending from the support part SP in the third direction DR3 and the second part B2 extending parallel to the first direction DR1 from a point spaced apart from the first deposition source DS1 and the second deposition source DS2 in the third direction DR3. When the first deposition process DP1 is performed, the second part B2 may partially overlap the first region A1 and the second region A2 on the plane. After the first deposition process DP1 is completed, the second part B2 of the barrier BR may move in the direction opposite to the first direction DR1 and may make contact with the outer wall of the chamber CB. Since the second part B2 of the barrier BR makes contact with the outer wall of the chamber CB, the first deposition source DS1 may be sealed by the support part SP and the second part B2 of the barrier BR. The sealed first deposition source DS1 may not affect the second deposition process DP2 (refer to FIG. 10D) to be performed later, and thus the deposition method may be performed with improved reliability.

Referring to FIGS. 9 and 10D, the second deposition process DP2 may be performed by the second deposition source DS2 (S500). Since the second deposition process DP2 is performed after the first deposition process DP1 is completed, the second deposition process DP2 may be performed on the first deposition layer DPL1. The second deposition process DP2 may include a process of supplying the process gas into the inner space of the chamber CB and a process of applying the second power supply voltage to the second deposition source DS2.

In the process of supplying the process gas into the inner space of the chamber CB, the gas supply bar GSB may spray the process gas into the inner space of the chamber CB. The process gas supplied from the gas supply unit GS disposed outside the chamber CB may be dispersed through the gas supply bar GSB and may be sprayed into the inner space of the chamber CB. The gas supply unit GS may be disposed outside the chamber CB. The process gas may be an inert gas. In an embodiment, for example, the inert gas may be argon (Ar) gas, but is not limited thereto. The inert gas may be formed into plasma and may be used to separate particles constituting the second target TG2.

In the process of applying the second power supply voltage to the second deposition source DS2, the second target TG2 may be rotated by the rotary actuator RD. The process gas sprayed to the second target TG2 may be formed into plasma and may collide with the second target TG2 to separate particles constituting the second target TG2. The separated particles may be deposited onto the first deposition layer DPL1 to form the second deposition layer DPL2 on the first deposition layer DPL1. Since the second target TG2 rotates, the second deposition layer DPL2 may be continually and uniformly deposited onto the first deposition layer DPL1 even though the particles constituting the second target TG2 are separated from one side of the surface of the second target TG2 by the plasma.

The second deposition layer DPL2 may be formed in a state in which the substrate SB is fixedly disposed on the substrate holder SH. As the second deposition process DP2 is performed by the plurality of second targets TG2 for a longer period of time than the first deposition process DP1 in the state in which the substrate SB is fixedly disposed on the substrate holder SH, the thickness of the second deposition layer DPL2 formed by the second deposition process DP2 may be greater than the thickness of the first deposition layer DPL1. In an embodiment, the second deposition layer DPL2 may have a thickness of about 5000 Å or greater.

Referring to FIG. 10E, after the second deposition process DP2 is completed, the substrate SB may move in the first direction DR1 and may exit the chamber CB through the chamber outlet CX. As the first deposition process DP1 and the second deposition process DP2 are performed in the inner space of the chamber CB according to an embodiment of the present disclosure to form the first deposition layer DPL1 and the second deposition layer DPL2 on the substrate SB, the number of chambers required for the deposition process may be reduced, and thus the deposition apparatus may have a simplified structure.

Referring back to FIGS. 8B and 9, in an alternative embodiment, before the process in which the substrate SB exits the chamber CB through the first chamber outlet CX, the third deposition process DP3 may be performed by the third deposition source DS3 while the substrate SB moves in the first direction DR1.

Before the process in which the substrate SB exits the chamber CB through the first chamber outlet CX, the third deposition process may be additionally performed by the third deposition source DS3 illustrated in FIG. 8B while the substrate SB moves in the first direction DR1.

The third deposition process is substantially the same as the first deposition process DP1 (refer to FIG. 10B), and therefore any repetitive detailed description thereof will be omitted. Although not illustrated, a third deposition layer may be formed on the second deposition layer DPL2 since the third deposition process is performed after the second deposition process is completed. The third deposition layer may be formed by the third deposition process while the substrate SB moves in the first direction DR1. Since the third deposition layer is formed while the substrate SB moves in the first direction DR1, the third deposition process may be evenly performed on the second deposition layer DPL2, and thus the flatness may be increased, as compared with when deposition is performed in a state in which the substrate SB is fixed. In addition, by reducing the deposition time, the third deposition layer may be formed to be thin. In an embodiment, the third deposition layer may have a thickness in a range of about 10 Å to about 30 Å.

Although not illustrated, a fourth deposition process or a fifth deposition process may be additionally performed after the third deposition process is performed. When the fourth deposition process or the fifth deposition process is performed, a fourth deposition source or a fifth deposition source may be additionally disposed in the inner space of the chamber CB, and a fourth deposition layer or a fifth deposition layer may be additionally disposed on the substrate SB.

According to embodiments of the present disclosure, the first and second deposition processes may be performed in a single chamber. Accordingly, the number of chambers used for deposition may be reduced, and thus the deposition apparatus may have a simplified structure.

In such embodiments, the first deposition process may be performed while the substrate moves in the inner space of the chamber, and the second deposition process may be performed in the state in which the substrate is fixed. Accordingly, the flatness of the first deposition layer may be improved at the same time that the thickness of the first deposition layer formed by the first deposition process is reduced. The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition apparatus comprising:
a chamber in which an inner space is defined;
a movement device which moves a substrate to which a deposition material is provided; and
a deposition source accommodated in the inner space, wherein the deposition source provides the deposition material,
wherein the deposition source includes:
a first deposition source which performs a first deposition process while the substrate is moved in a first direction by the movement device; and
a second deposition source which performs a second deposition process on the substrate after the first deposition process.

2. The deposition apparatus of claim 1, wherein a first region, in which the first deposition process is performed, and a second region, in which the second deposition process is performed, are defined in the inner space of the chamber, and
wherein the second region is adjacent to the first region in the first direction.

3. The deposition apparatus of claim 2, wherein the chamber includes a chamber inlet through which the substrate enters the inner space of the chamber, and
wherein the first region is adjacent to the chamber inlet.

4. The deposition apparatus of claim 2, further comprising:
a barrier between the first region and the second region,
wherein the barrier includes a first part and a second part.

5. The deposition apparatus of claim 4, wherein the second part partially overlaps the first region and the second region on a plane.

6. The deposition apparatus of claim 4, wherein the second part moves in a direction opposite to the first direction to overlap an entire portion of the first region on a plane to seal the first deposition source before the second deposition process is performed.

7. The deposition apparatus of claim 1, wherein the first deposition source includes a first target,
wherein the second deposition source includes a second target.

8. The deposition apparatus of claim 7, wherein the second target includes a plurality of second targets, and
wherein the first target has a number less than a number of the second targets.

9. The deposition apparatus of claim 7, wherein the first target has a rectangular cross-sectional shape, and
wherein the first target is disposed to be inclined with respect to the substrate.

10. The deposition apparatus of claim 7, wherein the first deposition source further includes a first magnet and a shielding layer disposed between the first target and the first magnet.

11. The deposition apparatus of claim 7, wherein the second target has a cylindrical shape extending in a second direction perpendicular to the first direction.

12. The deposition apparatus of claim 11, wherein the second deposition source further includes:
a rotary actuator which rotates the second target; and
a second magnet disposed inside the second target.

13. The deposition apparatus of claim 1, further comprising:
a third deposition source which performs a third deposition process while the substrate is moved in the first direction by the movement device after the second deposition process.

14. The deposition apparatus of claim 1, further comprising:
a voltage application device which applies a power supply voltage to the first and second deposition sources.

15. The deposition apparatus of claim 1, further comprising:
a substrate holder which fixes the substrate onto the second deposition source.

16. A deposition method comprising:
providing a deposition apparatus, wherein the deposition apparatus includes a chamber, a deposition source disposed in an inner space of the chamber and including a first deposition source and a second deposition source, a movement device which moves a substrate to which a deposition material is provided, and a substrate holder which fixes the substrate;
loading the substrate into the inner space of the chamber through the movement device;
performing a first deposition process using the first deposition source while the substrate moves in a first direction;
fixing the substrate to the substrate holder disposed over the second deposition source; and
performing a second deposition process using the second deposition source after the substrate is fixed to the substrate holder.

17. The deposition method of claim 16, wherein the performing the first deposition process includes:
applying vacuum pressure to the inner space of the chamber;
supplying a process gas into the inner space of the chamber; and
applying a power supply voltage to the first deposition source.

18. The deposition method of claim 16, wherein the deposition apparatus further includes a barrier disposed between the first deposition source and the second deposition source, and
wherein the deposition method further comprises sealing the first deposition source using the barrier before the performing the second deposition process.

19. The deposition method of claim 16, wherein a first deposition layer is formed on the substrate by the first deposition process,
wherein a second deposition layer is formed on the first deposition layer by the second deposition process, and
wherein the first deposition layer is thinner than the second deposition layer.

20. The deposition method of claim 16, wherein the deposition source further includes a third deposition source, and
wherein the deposition method further comprises performing a third deposition process using the third deposition source while the substrate moves in the first direction after the performing the second deposition process.
